(19) United States
(12) Patent Application Publication
(10) Pub. No.: US 2025/0062218 A1
(43) Pub. Date: Feb. 20, 2025

(54) METAL INSULATOR METAL CAPACITOR (MIM CAPACITOR)

(71) Applicant: INTERNATIONAL BUSINESS MACHINES CORPORATION, ARMONK, NY (US)

(72) Inventors: ATSUSHI OGINO, Fishkill, NY (US); Dureseti Chidambarrao, Weston, CT (US); Baozhen Li, South Burlington, VT (US); Matthew Stephen Angyal, Stormville, NY (US); Yueming Xu, Wappingers Falls, NY (US); Nan JING, Fishkill, NY (US)

(21) Appl. No.: 18/449,941

(22) Filed: Aug. 15, 2023

(51) Int. Cl. H01L 23/522; H01L 23/528

(52) U.S. Cl. CPC H01L 23/5223; H01L 23/5226; H01L 23/5283; H01L 28/60

(57) ABSTRACT

A semiconductor device including a metal insulator metal capacitor (MIM capacitor) within back end of line circuitry of the semiconductor device, and an outer plate contact opening of an outer plate of the MIM capacitor, wherein a portion of an inner plate is removed, where portions of the outer plate are removed from corners of the outer plate opening. A metal insulator metal capacitor (MIM capacitor) within back end of line circuitry of the semiconductor device, and a non-rectangular contact opening of an outer plate of the MIM capacitor. Forming a metal insulator metal capacitor (MIM capacitor) within back end of line circuitry of the semiconductor device, and an outer plate contact opening of an outer plate of the MIM capacitor, where a portion of an inner plate is removed, where portions of the outer plate are removed from corners of the outer plate opening.

### BACKGROUND

The present invention relates, generally, to the field of semiconductor manufacturing, and more particularly to a metal-insulator-metal (MIM) capacitor.

MIM capacitors are a key element for integration of system-on-chips, improving both circuit performance and down-scaling capability. A typical MIM capacitor includes an outer electrode, a dielectric/insulator layer and an inner electrode. Voltage is applied across the electrodes which results in charge storage within the formed capacitor configuration. MIM capacitors are used in functional circuits such as mixed signal circuits, analog circuits, radio frequency (RF) circuits, dynamic random access memory (DRAM), embedded DRAM, and logic operation circuits. In general, for a MIM capacitor in an RF application, a dielectric loss must be extremely small, and a series resistance of the wiring should be minimized for high frequency applications. This indicates that it is desirable to use short interconnect wires with a low specific resistance. A MIM capacitor integrated in back end of line (BEOL) metallization is suitable to fulfill these requirements.

The MIM capacitor is usually embedded into upper back end of line (BEOL) layers. Traditional methods of fabricating a MIM capacitor include stacking of multiple MIM capacitor layers that involve numerous lithography and etching steps

### SUMMARY

According to an embodiment of the present invention, a semiconductor device is provided. The semiconductor device including a metal insulator metal capacitor (MIM capacitor) within back end of line circuitry of the semiconductor device, and an outer plate contact opening of an outer plate of the MIM capacitor, wherein a portion of an inner plate is removed, where portions of the outer plate are removed from corners of the outer plate opening.

According to an embodiment of the present invention, a semiconductor device is provided. The semiconductor device including a metal insulator metal capacitor (MIM capacitor) within back end of line circuitry of the semiconductor device, and a non-rectangular contact opening of an outer plate of the MIM capacitor.

According to an embodiment of the present invention, a method is provided. The method including forming a metal insulator metal capacitor (MIM capacitor) within back end of line circuitry of the semiconductor device, and an outer plate contact opening of an outer plate of the MIM capacitor, where a portion of an inner plate is removed, where portions of the outer plate are removed from corners of the outer plate opening.

### BRIEF DESCRIPTION OF THE DRAWINGS

The following detailed description, given by way of example and not intended to limit the invention solely thereto, will best be appreciated in conjunction with the accompanying drawings, in which:

FIG. 1 illustrates a top view of a semiconductor structure, according to an exemplary embodiment;

FIGS. 2 and 3 each illustrate a cross-sectional view of the semiconductor structure according to FIG. 1, along section line X1-X1 and X2-X2, respectively, according to an exemplary embodiment;

FIG. 4 illustrates a top view of the semiconductor structure, and illustrations formation of an inner electrode, according to an exemplary embodiment;

FIGS. 5 and 6 each illustrate a cross-sectional view of the semiconductor structure according to FIG. 4, along section line X1-X1 and X2-X2, respectively, according to an exemplary embodiment;

FIG. 7 illustrates a top view of the semiconductor structure, and illustrations formation of an outer electrode, according to an exemplary embodiment; and

FIGS. 8, 9, 10 and 11 each illustrate a cross-sectional view of the semiconductor structure according to FIG. 7, along section line X1-X1, X2-X2, Z1-Z1 and Z2-Z2, respectively, according to an exemplary embodiment;

FIG. 12 illustrates a top view of an alternate semiconductor structure, according to an exemplary embodiment;

FIG. 13 illustrates a top view of an alternate semiconductor structure, according to an exemplary embodiment;

FIG. 14 illustrates a cross-sectional view of an alternate semiconductor structure along section line X1-X1, according to an exemplary embodiment; and

FIG. 15 illustrates a cross-sectional view of an alternate semiconductor structure along section line X1-X1, according to an exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiment set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

The present invention relates, generally, to the field of semiconductor manufacturing, and more particularly to a metal-insulator-metal (MIM) capacitor.

There is a high demand for on chip capacitors, such as MIM capacitors, in high performance chip designs. Advanced technologies usually offer two types of back end of line (BEOL) capacitors, a plane high capacitance density MIM capacitor at higher metal, and metal finger arrays which provides a low capacitance density. A plane high capacitance density MIM capacitor has planar metal plates with a high-k dielectric thin film (such as HfO2, Al2O3, ZrO2. Ta2O5, or a combination) sandwiched between the planar metal plates. The plane high capacitance density MIM capacitor is built between two different metal wire levels. A metal finger array MIM capacitors include an array of parallel metal lines from the same metal wire level. These parallel metal lines serve as electrodes, and the inter-line dielectric (ILD) (usually a low k or a silicon-based oxide) between the metal lines serves as insulator layer for the capacitor. For some high performance devices, e.g. SRAM, there is a need for “local” decoupling capacitors to boost performance and yield. Metal finger arrays have a capacitance density which is too low, and would need a large area of the chip to increase the capacitance. A local capacitor, near electronic components of the chip is preferred, such as a MIM capacitor.

A MIM capacitor may have two or more plates. In an embodiment, a MIM capacitor may include an outer plate and an inner plate or electrode, with an insulator between the outer plate and the inner plate. The outer plate and the inner plate each may be referred to as a metal layer and alternatively may be referred to as an electrode. There may be a first contact and a first via connected to the outer plate and a second via and a second contact may be connected to the inner plate. The first via and the second via may each connect between Mx metal lines, for example between Mx-1 metal line and Mx metal line.

Following is an example of a three plate MIM capacitor. Traditionally, a first metal layer or plate may be formed. A portion of the first metal layer may be removed, creating a first contact slot, or a first window. The first contact slot may have a square or rectangular shape from a top view. A first dielectric layer, or a first insulator layer may be conformally formed on the first metal layer and in the first contact slot. The first dielectric may be part of the insulator layer of the MIM capacitor. A second metal layer may be conformally formed on the first dielectric layer. The second metal layer may be an inner plate of the MIM capacitor. A portion of the second metal layer of the outer plate may be removed, creating a second contact slot, or a second window. The second contact slot may have a square or rectangular shape from a top view. A second dielectric layer, or a second insulator layer, may be conformally formed on the second metal layer and in the second contact slot. The second dielectric layer may be part of the insulator layer of the MIM capacitor. A third metal layer may be formed. A portion of the third metal layer may be removed, creating a third opening, or a third contact slot. The third contact slot may have a square or rectangular shape from a top view. The third contact slot may be vertically aligned above the first contact slot.

A first via may be formed through the first metal layer and the third metal layer, forming a first contact to the outer plate, where the outer plate is the first metal layer and the third metal layer. The first via may be formed in the first contact slot where a first contact slot and the third contact slot contact slot are vertically aligned. The first dielectric separates the first metal layer from the second metal layer. The second dielectric separates the second metal layer from the third metal layer. A second via may be formed through the second metal layer, forming a second contact to the inner plate, where the inner plate is the second metal layer. The second via may be formed in the second contact slot.

Corners of the first contact slot and corners of the second contact slot may be subject to weakness and degradation and may cause shorts and failures of the structure using the MIM capacitor. The corners of the first contact slot and the second contact slot are exposed to stress which can reduce reliability of the structure using the MIM capacitor. The stress is caused by metal stress change near the contact opening area (or contact slot) because the contact slot may release the stress in the metal layer around the contact slot, resulting in a stress delta to the metal below and/or above. The stress delta may be greatest near the contact slot corners because the metal film stress will be released in two orthogonal lateral directions. A stress delta at contact slot corners may cause adhesion weakness between metal and high-k insulator dielectric, resulting in a lower Vbd voltage and/or shorter TDDB lifetime. Vdb is Voltage break down. TDDB is time dependent dielectric breakdown.

In this invention, a MIM capacitor may be formed with contact slots which are non-rectangular, which may reduce stress on corners of a first contact slot and a second contact slot. The non-rectangular contact slot or contact opening may improve reliability of the structure using the MIM capacitor. In a first embodiment, there are open windows in each of the plates of the inner plate and each of the plates of the outer plate. Specifically, a first outer plate may be formed. An inner contact slot in the first outer plate is formed by removing a portion of the first outer plate. The inner contact slot is positioned in a location for a contact to an inner plate. Additionally, four outer plate corner openings are formed by removing portions of the first outer plate. The four outer plate corner openings are each positioned to align with corner of an outer contact slot. An inner plate may be formed. The outer contact slot in the inner plate is formed by removing a portion of the inner plate. The outer contact slot is positioned in a location for a contact to the outer plate. Additionally, four inner plate corner openings are formed by removing portions of the inner plate. The four inner plate corner openings are each positioned to align with a corner of the inner contact slot.

In the first embodiment, stress is reduced by eliminating the highest stress locations in the metal where would have stress from two orthogonal directions. This may reduce the stress by up to 50 percent, significantly improving reliability of the structure using the MIM capacitor.

In a second embodiment, first contact slot and a second contact slot may a non-rectangular shape from above, such as, circular, oval, octagon shape or a polygonal shape with greater than four edges, when viewed from above. Forming contact slots with shapes which are non-rectangular reduces the worst stress point which has two orthogonal directional stress to more spread.

The present invention relates, generally, to the field of semiconductor manufacturing, and more particularly to a metal-insulator-metal (MIM) capacitor.

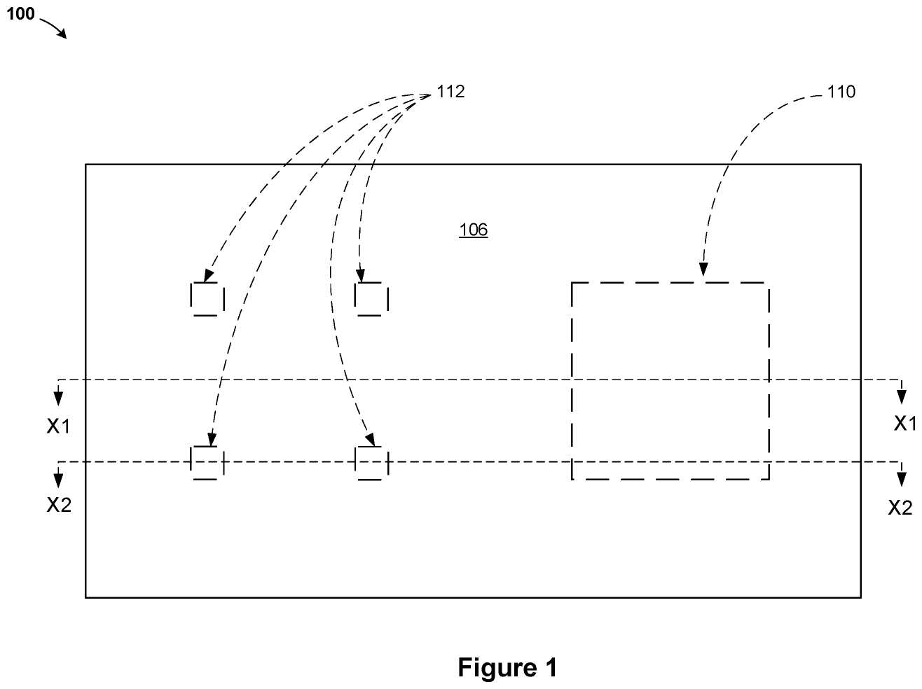

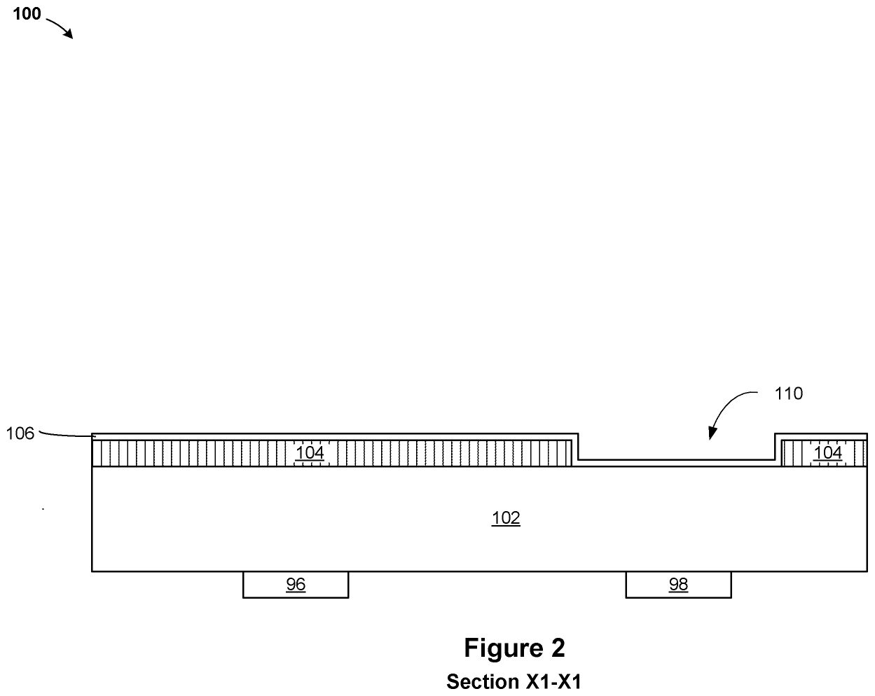

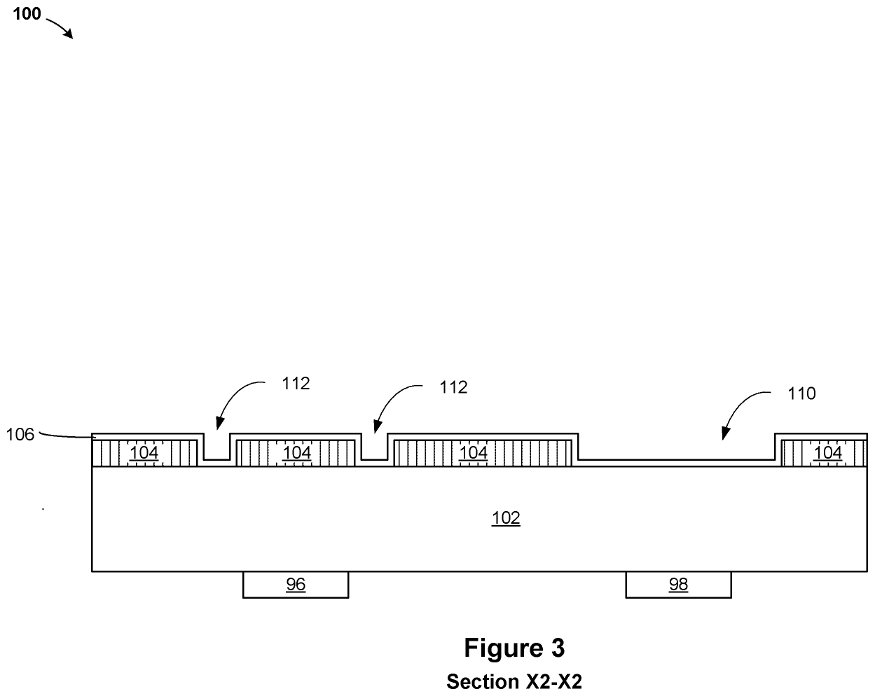

Referring now to FIGS. 1, 2 and 3, a semiconductor structure 100 (hereinafter “structure”) at an intermediate stage of fabrication is shown according to an exemplary embodiment. FIG. 1 is a top view of the structure 100. FIG. 2 is a cross-sectional view of the structure 100 along section line X1-X1. FIG. 3 is a cross-sectional view of the structure 100 along section line X2-X2. The structure 100 may be formed or provided. The structure 100 may include an Mx-1 metal line 96, an Mx metal line 98, an inter-layer dielectric (hereinafter “ILD”) 102, a first plate 104, and an insulator 106.

The dashed lines of the corner opening 112 and the opening 110 indicate these openings in a metal plate are below an upper surface of the top view of the structure 100 shown in FIG. 1.

The structure 100 may include several back end of line (“BEOL”) layers. In general, the back end of line (BEOL) is where individual devices (transistors, capacitors, resistors, etc.) are interconnected with wiring on a semiconductor wafer.

The Mx-1 metal line 96 and the Mx-1 metal line 98 may each be composed of, for example, tantalum nitride (TaN), tantalum (Ta), titanium (Ti), titanium nitride (TiN), cobalt (Co) or a combination thereof. There may be any number of Mx-1 metal lines 96 and Mx-1 metal lines 98, on the structure 100. The Mx-1 metal line 96 and the Mx-1 metal line 98 may be formed by methods known in the arts.

The ILD 102 may be formed by depositing or growing a dielectric material on the BEOL layers, followed by a chemical mechanical polishing (CMP) or etch steps. The ILD 102 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques. In an embodiment, the ILD 102 may include one or more layers. In an embodiment, the ILD 102 may include any dielectric material such as tetraethyl orthosilicate (TEOS), silicon oxide (SiOx), silicon nitride (SiNx), silicon boron carbonitride (SiBCN), NBLOK, a low-k dielectric material (with k<4.0) such as SiCOH, SiCNH and SiCNOH, including but not limited to, silicon oxide, spin-on-glass, a flowable oxide, a high-density plasma oxide, borophosphosilicate glass (BPSG), or any combination thereof or any other suitable dielectric material. NBLOK is a trademark of Applied Materials, Inc.

The first plate 104 may be formed from a conductive material layer which is blanket deposited on top of the structure 100, and directly on an upper horizontal surface of the ILD 102. The conductive material layer may include materials such as, for example titanium nitride (TiN), tantalum nitride (TaN). The conductive material can be formed by for example, chemical vapor deposition (CVD), physical vapor deposition (PVD), and atomic layer deposition (ALD) or a combination thereof.

An opening 110 may be formed by removal of portions of the first plate 104, exposing an upper horizontal surface of the ILD 102, by selective etching, such as reactive etching (RIE). In an embodiment, the opening 110 may be rectangularly shaped when viewed from the top view of FIG. 1. In an alternate embodiment, the opening 110 may be circular, oval or a polygonal shape. The opening 110 may be vertically aligned above the Mx-1 metal line 98.

A corner opening 112 may be formed by removal of portions of the first plate 104, exposing an upper horizontal surface of the ILD 102, by selective etching, such as reactive etching (RIE). In an embodiment, the corner opening 112 may be rectangularly shaped when viewed from the top view of FIG. 1. In an embodiment, there may be four corner openings 112. In an alternate embodiment, the corner opening 112 may be circular, oval or a polygonal shape. The corner opening 112 may be vertically aligned above the Mx-1 metal line 96.

The insulator 106 may be conformally deposited on the structure 100. The insulator 106 may be formed by depositing or growing a dielectric material on the structure 100, on the first plate 104 and on the ILD 102, partially filling the opening 110 and the opening 112. The insulator 106 may be deposited using typical deposition techniques, for example, atomic layer deposition (ALD), molecular layer deposition (MLD), chemical vapor deposition (CVD), physical vapor deposition (PVD), high density plasma (HDP) deposition. In an embodiment, the insulator 106 may include any high-k dielectric and may include, but is not limited to HfO₂, ZrO₂. La₂O₅, Al₂O₃, TiO₂, a high-k dielectric material (with k>4.0), or a combination thereof.

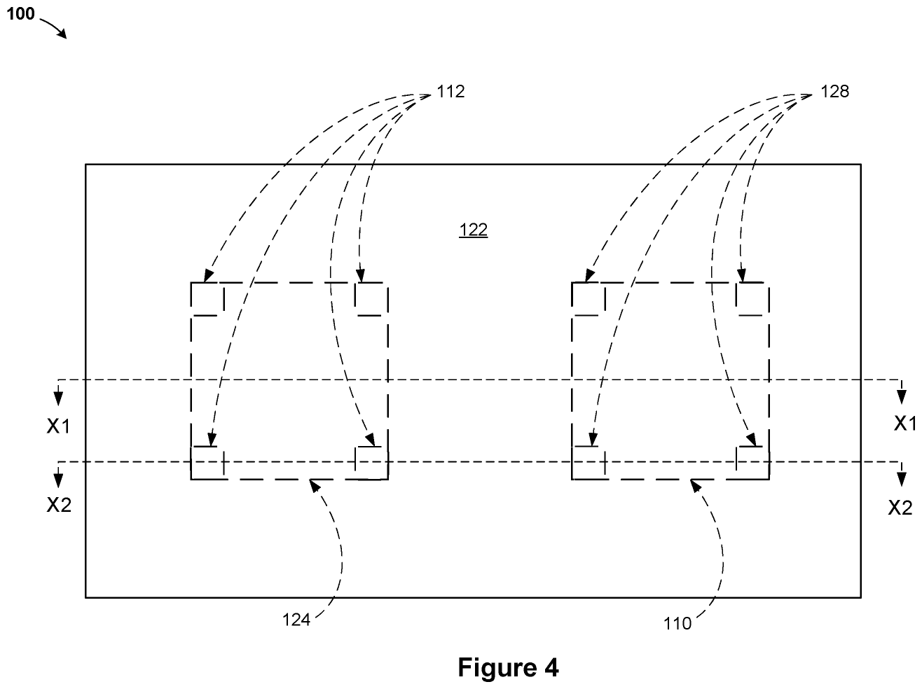

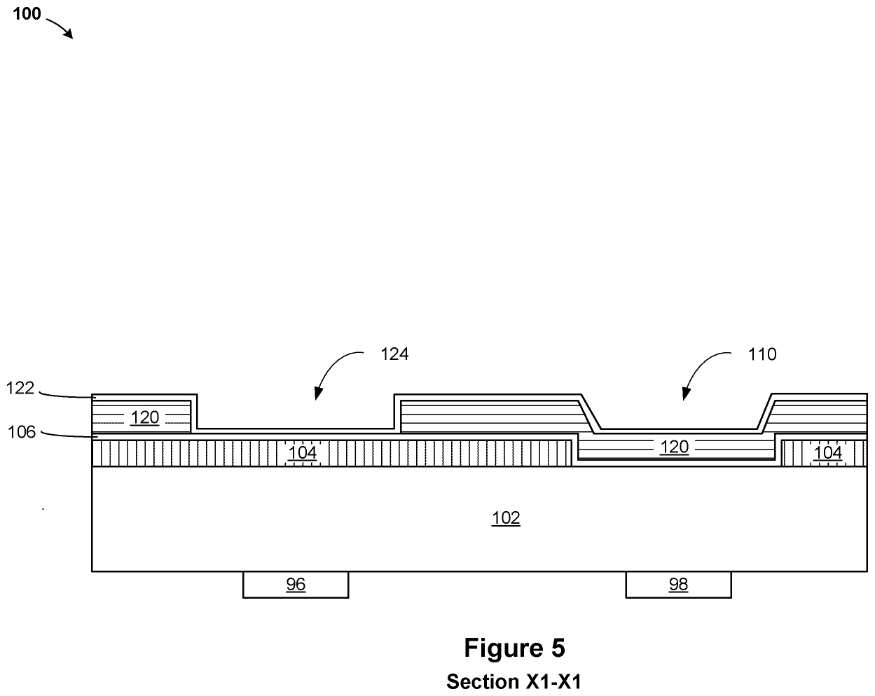

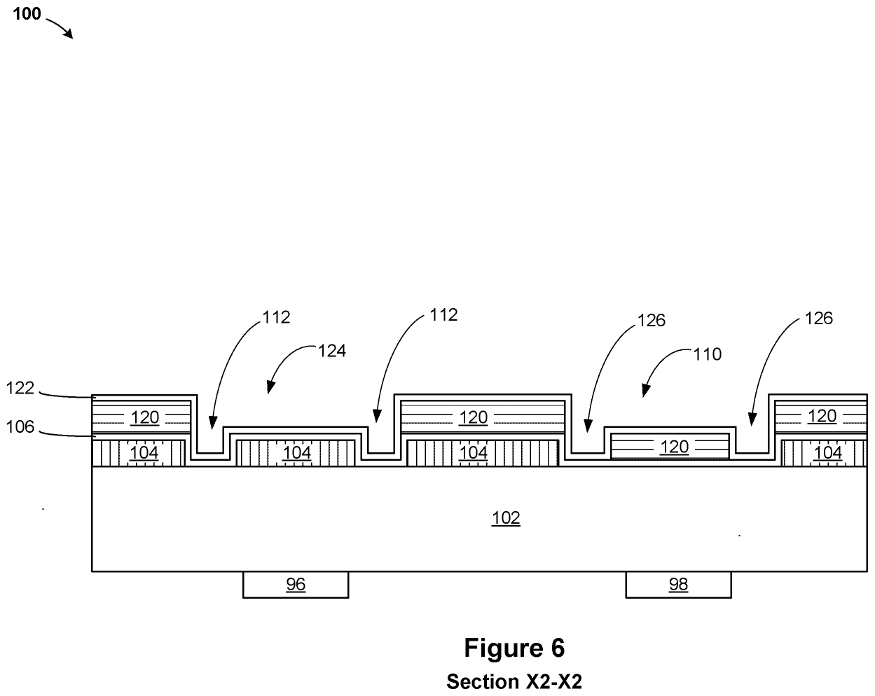

Referring now to FIGS. 4, 5 and 6, the structure 100 is shown according to an exemplary embodiment. FIGS. 4 and 5 are each a cross-sectional view of the structure 100 along section lines X1-X1 and X2-X2, respectively. An inner plate 120 and an insulator 122 may be formed.

The dashed lines of the corner opening 112, the opening 124, the opening 110 and the corner opening 126 indicate these openings in a metal plate are below an upper surface of the top view of the structure 100 shown in FIG. 4.

The inner plate 120 may be formed from a conductive material layer which is blanket deposited on top of the structure 100, and directly on an upper horizontal surface of the insulator 106, filling the opening 110 and partially filling the corner opening 112. The conductive material layer may include materials such as, for example titanium nitride (TiN), tantalum nitride (TaN), copper (Cu), ruthenium (Ru), cobalt (Co), tungsten (W). The conductive material can be formed by for example, chemical vapor deposition (CVD), physical vapor deposition (PVD), and atomic layer deposition (ALD) or a combination thereof.

An opening 124 may be formed by removal of portions of the inner plate 120, exposing an upper horizontal surface of the insulator 106, by selective etching, such as reactive etching (RIE). In an embodiment, the opening 124 may be rectangularly shaped when viewed from the top view of FIG. 1. In an alternate embodiment, the opening 124 may be circular, oval or a polygonal shape. Additional portions of the inner plate 120 may be removed to maintain the four corner openings 112. The opening 124 may be vertically aligned above the four corner openings 112, such that each of the corner openings 112 have vertical side surfaces which are vertically aligned with two vertical side surfaces of the opening 124 and the corner openings 112 are aligned below a corner of the opening 124. The opening 124 and the corner openings 112 are vertically aligned above the Mx-1 metal line 96.

A corner opening 126 may be formed by removal of further portions of the inner plate 120, exposing an upper horizontal surface of the inner plate 120, by selective etching, such as reactive etching (RIE). In an embodiment, the corner opening 126 may be rectangularly shaped when viewed from the top view of FIG. 1. In an embodiment, there may be four corner openings 126. In an alternate embodiment, the corner opening 126 may be circular, oval or a polygonal shape. The four corner openings 126 may be vertically aligned in the opening 110, such that each of the four corner openings 126 have vertical side surfaces which are vertically aligned with two vertical side surfaces of the opening 110. The opening 110 and the corner openings 126 are vertically aligned the Mx-1 metal line 98.

The insulator 122 may be conformally deposited on the structure 100. The insulator 122 may be formed as described for the insulator 106. The insulator 122 may partially fill the opening 124, the corner openings 112, the opening 110 and the corner opening 126. The insulator 122 may be on an upper horizontal surface and a vertical side surface of the inner plate 120 and on an upper horizontal surface and a vertical side surface of the insulator 106.

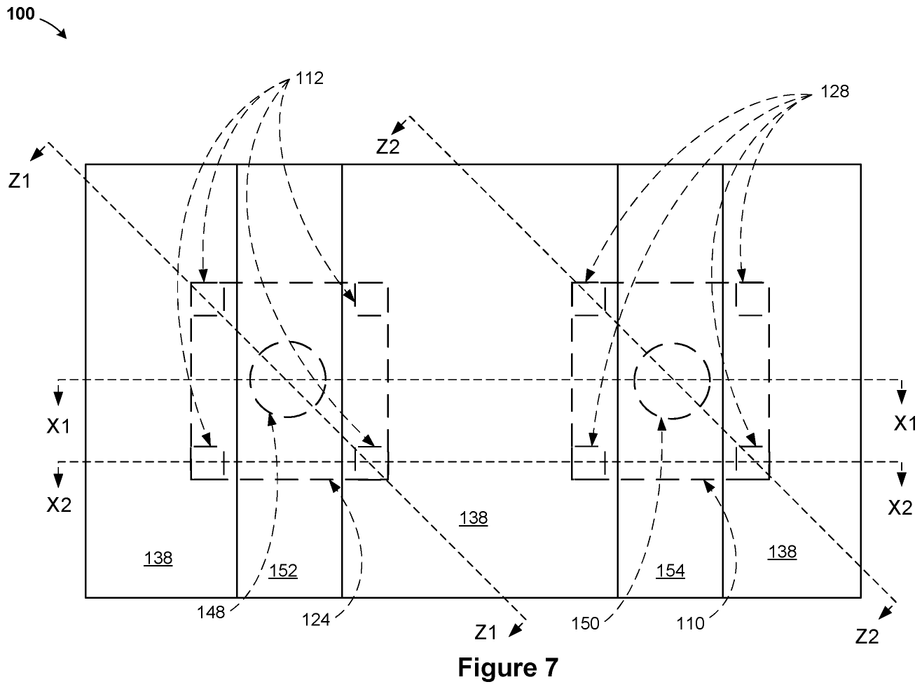

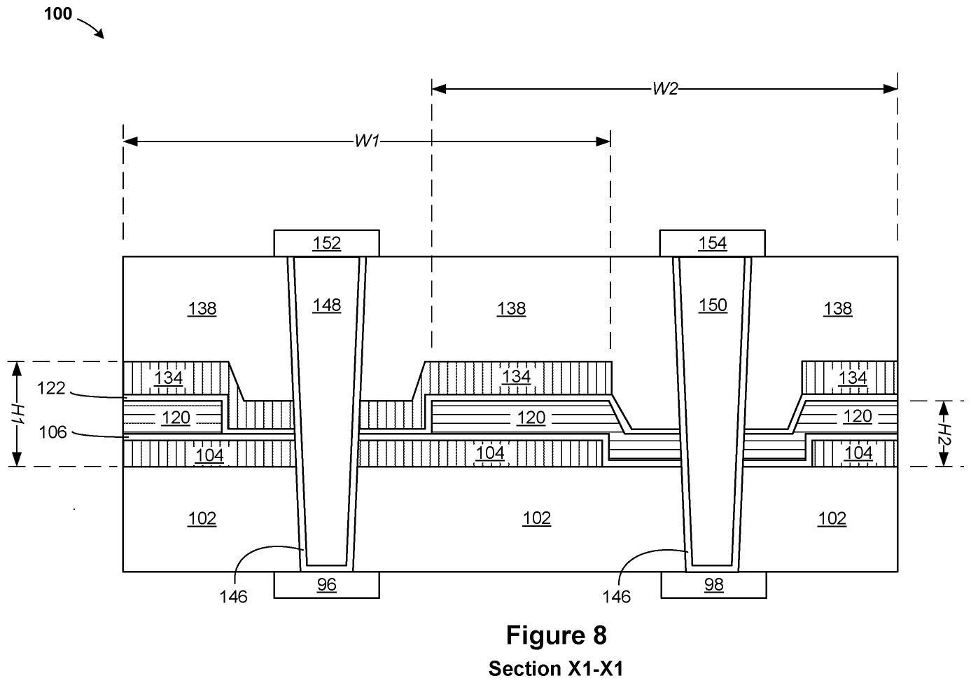

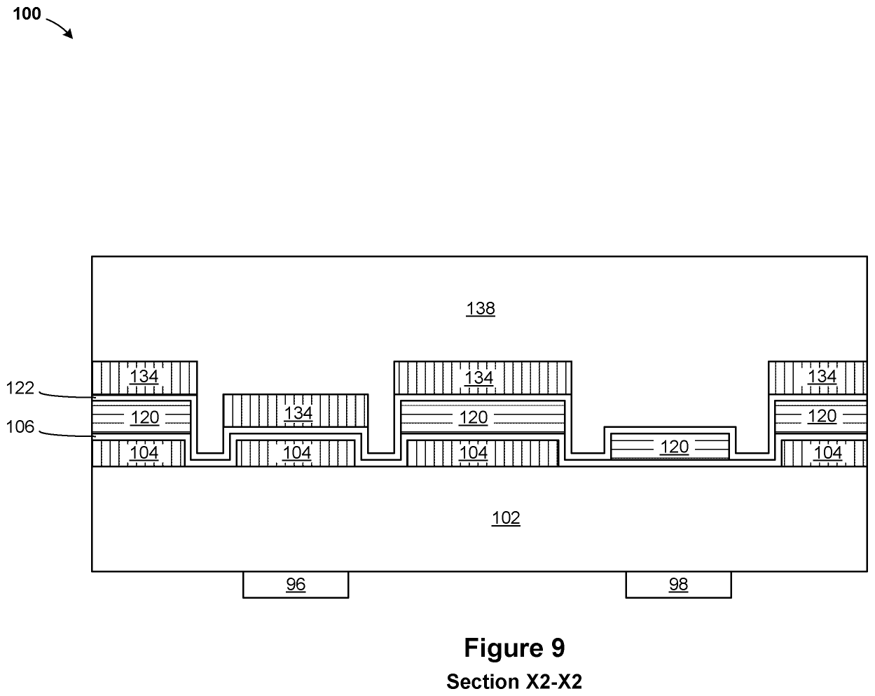

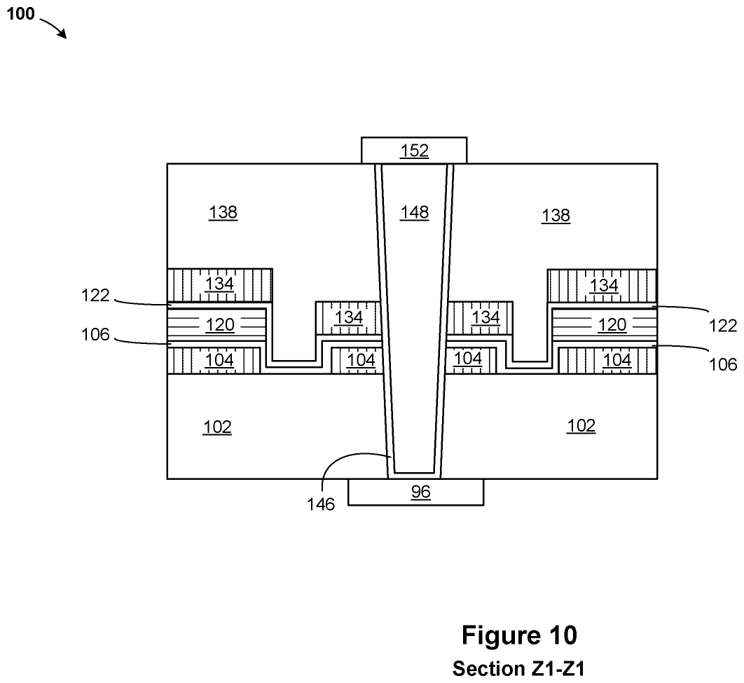

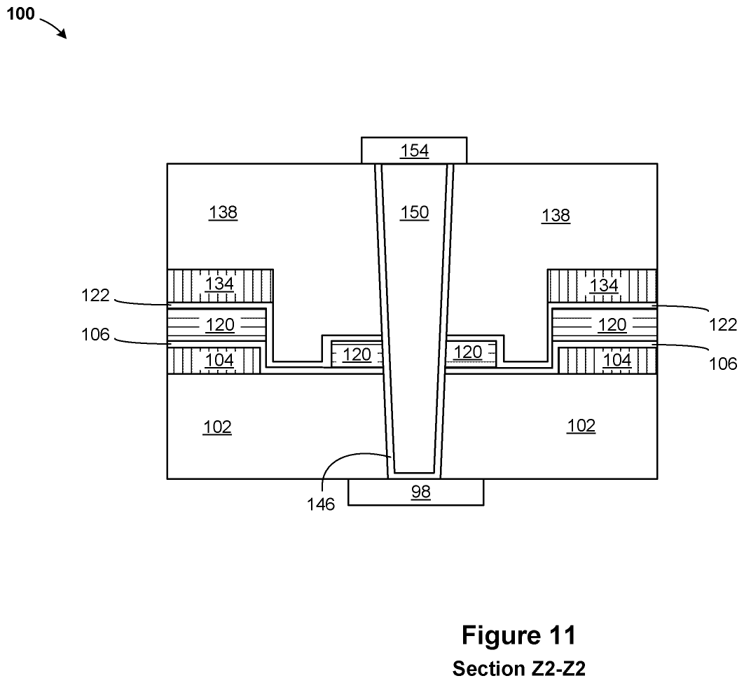

Referring now to FIGS. 7, 8, 9, 10 and 11, the structure 100 is shown according to an exemplary embodiment. FIG. 7 is a top view of the structure 100. FIGS. 8 and 9 are each a cross-sectional view of the structure 100 along section lines X1-X1 and X2-X2, respectively. FIGS. 10 and 11 are each a cross-sectional view of the structure 100 along section lines Z1-Z1 and Z2-Z2, respectively. FIGS. 10 and 11 are 45 degrees off from FIGS. 8 and 9. A second plate 134 and an inter-layer dielectric (hereinafter “ILD”) 138 may be formed. A liner 146, a via 148, a via 150, an Mx metal line 152 and an Mx metal line 154 may be formed.

The dashed lines of the corner opening 112, the opening 124, the opening 110 and the corner opening 126 indicate these openings in a metal plate are below an upper surface of the top view of the structure 100 shown in FIG. 7.

The second plate 134 may be formed from a conductive material layer which is blanket deposited on top of the structure 100, and directly on an upper horizontal surface of the insulator 122, partially filling the opening 124, the corner openings 112, the opening 110 and the corner openings 126. The conductive material layer may include materials such as, for example titanium nitride (TiN), tantalum nitride (TaN), copper (Cu), ruthenium (Ru), cobalt (Co), tungsten (W). The conductive material can be formed by for example, chemical vapor deposition (CVD), physical vapor deposition (PVD), and atomic layer deposition (ALD) or a combination thereof.

Portions of the second plate 134 may be removed to maintain the four corner openings 112 and expose an upper horizontal surface of the insulator 122. Additional portions of the second plate 134 may be removed to maintain the four corner openings 126 and the opening 110, exposing an upper horizontal surface of the insulator 122.

The ILD 138 may be formed as described for the ILD 102, conformally on the structure 100. The ILD 138 may be formed on the upper horizontal and vertical side surfaces of the second plate 134. The ILD 138 may be formed on the upper horizontal and vertical side surfaces of the insulator 122. The ILD 138 may fill the opening 124, the corner openings 112, the opening 110 and the corner openings 126.

A planarization process, such as, for example, chemical mechanical polishing (CMP), may be done to remove excess material from an upper horizontal surface of the structure 100 such that an upper horizontal surfaces of the ILD 138 is planar.

A first opening (not shown) may be formed in the structure 100. The first opening (not shown) may be formed by removal of vertically aligned portions of the ILD 138, the second plate 134, the insulator 122, the insulator 106, the first plate 104, and the ILD 102, exposing an upper horizontal surface of the Mx-1 metal line 96.

A second opening (not shown) may be formed in the structure 100. The second opening (not shown) may be formed by removal of vertically aligned portions of the ILD 138, the insulator 122, the inner plate 120, the insulator 106 and the ILD 102, exposing an upper horizontal surface of the Mx-1 metal line 98.

The liner 146 may be formed in the first opening and in the second opening (not shown). The liner 146 may be formed along vertical side surfaces and lower horizontal surfaces of the first, second openings, on vertical side surfaces of the ILD 138, the second plate 134, the insulator 122, the insulator 106, the first plate 104, the inner plate 120, and the ILD 102. The liner 146 may be formed on horizontal upper surfaces of the Mx-1 metal line 96 and the Mx-1 metal line 98. The liner 146 may be composed of, for example, tantalum nitride (TaN), tantalum (Ta), titanium (Ti), titanium nitride (TiN), cobalt (Co) or a combination thereof. The liner 146 may be deposited a conventional deposition process such as, for example, CVD, plasma enhanced chemical vapor deposition (PECVD), PVD or ALD. The liner 146 may be 5 nm thick, although a thickness less than or greater than 5 nm may be acceptable.

In an embodiment, the via 148 and the via 150 are formed from a conductive material layer which is blanket deposited on top of the structure 100, and directly on an upper horizontal surface of the ILD 138, and directly on a top surface of the liner 146, filling the trench (not shown). The conductive material layer may include materials such as, for example, copper (Cu), ruthenium (Ru), cobalt (Co), aluminum (Al), tungsten (W), tantalum nitride (TaN) and titanium nitride (TiN). The conductive material can be formed by for example, electrochemical plating, chemical vapor deposition (CVD), physical vapor deposition (PVD), and atomic layer deposition (ALD) or a combination thereof. The via 148 and the via 150 are formed by damascene, or patterned from the conductive material layer, using known patterning and etching techniques. There may be any number of openings in the ILD 138, each filled with the liner 146 and the via 148 and the via 150, on the structure 100.

A planarization process, such as, for example, chemical mechanical polishing (CMP), may be done to remove excess material from an upper horizontal surface of the structure 100 such that upper horizontal surfaces of the via 148 and the via 150, the liner 146 and the ILD 138 are coplanar.

The Mx metal line 152 and the Mx metal line 154 may be formed as described for the Mx-1 metal line 96 and the Mx-1 metal line 98. There may be any number of Mx metal lines 152 and Mx metal lines 154 on the structure 100.

The second plate 134 and the first plate 104 form the outer plate of the MIM capacitor. The insulator 122 and the insulator 106 together form the insulator of the MIM capacitor. The inner plate 120 is part of the MIM capacitor. The outer plate, the insulator and the inner plate 120 form the MIM capacitor. The via 148 is a contact to the outer plate of the MIM capacitor. The via 148 is connected to the Mx-1 metal line 96 and to the Mx metal line 152. The via 150 is a contact to the inner plate of the MIM capacitor. The via 150 is connected to the Mx-1 metal line 98 and to the Mx metal line 154. This is an example of a three plate MIM capacitor.

The MIM capacitor has a plus sign shape when viewed from above, as shown in FIG. 7. The top view of FIG. 7 illustrates the via 148 connected to and surrounded by the outer plates of the second plate 134 and the first plate 104 in a first contact window. The first contact window was the opening 124. The first contact window does not have the outer plate of either the second plate 134 nor the first plate 104 in corners of the first contact window. The corners of the first contact window are corner openings 112. The via 150 is connected to and surrounded by the inner plate 120 in a second contact window. The first second window was the corner opening 126. The second contact window does not have the inner plate 120 in corners of the second contact window. The corners of the second contact window are corner openings 126.

A width, W1, of the outer plate, is greater than a height, H1, of the outer plate. A width, W2, of the inner plate 120, is greater than a height, H2, of the inner plate 120.

In this invention, the corners of the first contact window and the second contact window do not have the inner plate nor the outer plate, which reduces stress on the MIM capacitor and on a structure using the MIM capacitor. By removing the inner plate and the outer plate from each corner of the contact window, a reliability of the structure using the MIM capacitor is improved.

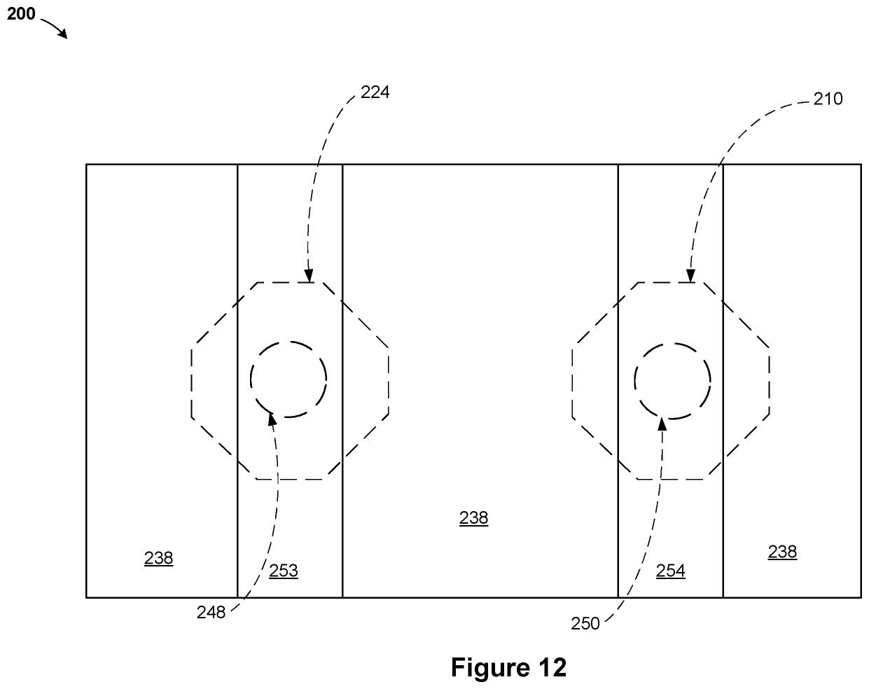

Referring now to FIG. 12, a semiconductor structure 200 (hereinafter “structure”) at an intermediate stage of fabrication is shown according to an exemplary embodiment. FIG. 12 is a top view of the structure 200. The structure 200 may be formed or provided. The structure 200 may include an inter-layer dielectric (hereinafter “ILD”) 238, an Mx metal line 252, an Mx metal line 254, an opening 224, a via 248, an opening 210 and a via 250.

The dashed lines of the opening 224, the via 248, the corner opening 226 and the via 250 indicate these openings in a metal plate are below an upper surface of the top view of the structure 200.

The structure 200 may be formed as described for the structure 100. Components in the structure 200 may be formed as described for components with similar names in the structure 100. The structure 200 may include a MIM capacitor. An outer metal plate may be connected to the Mx metal line 253 and the via 248. An inner metal plate may be connected to the Mx metal line 254 and the via 250. The structure 200 may differ from the structure 100 in an outline of a shape of the opening 224 and an outline of a shape of the opening 210. The outline of the shape of the opening 224 and the outline of the shape of the opening 210 may be an octagon shape from above. The structure 200 may have similar benefits as the structure 100.

In this invention, corners of the first contact window (or contact pad) and the second contact window (or contact pad) do not have the inner plate nor the outer plate, which reduces stress on the MIM capacitor and on a structure using the MIM capacitor. By removing the inner plate and the outer plate from each corner of the contact window, a reliability of the structure using the MIM capacitor is improved.

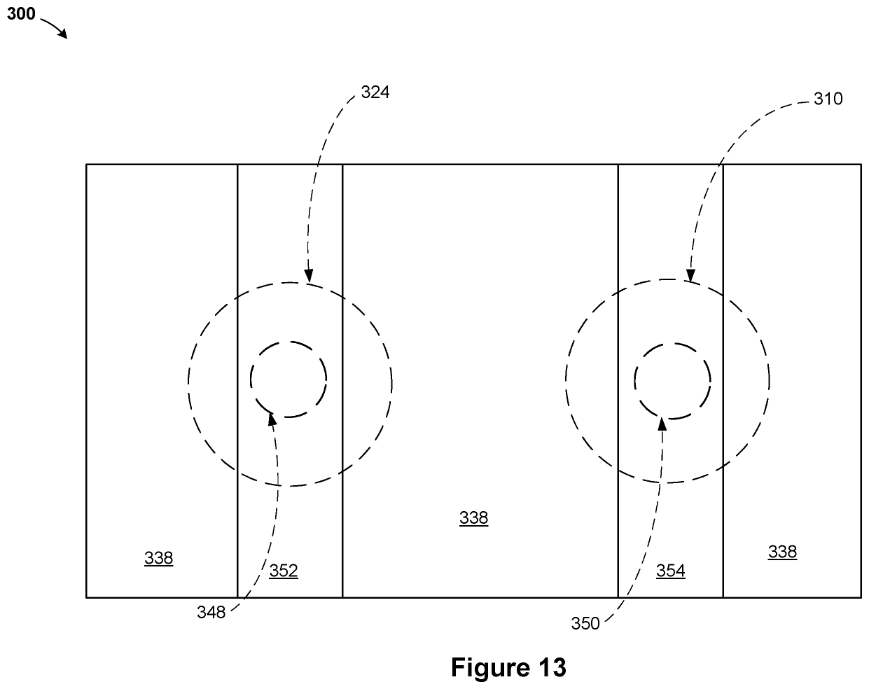

Referring now to FIG. 13, a semiconductor structure 300 (hereinafter “structure”) at an intermediate stage of fabrication is shown according to an exemplary embodiment. FIG. 13 is a top view of the structure 300. The structure 300 may be formed or provided. The structure 300 may include an inter-layer dielectric (hereinafter “ILD”) 338, an Mx metal line 352, an Mx metal line 354, an opening 324, a via 348, an opening 310 and a via 350.

The dashed lines of the opening 324, the via 348, the opening 310 and the via 350 indicate these openings in a metal plate are below an upper surface of the top view of the structure 300.

The structure 300 may be formed as described for the structure 100. Components in the structure 300 may be formed as described for components with similar names in the structure 100. The structure 300 may include a MIM capacitor. An outer metal plate may be connected to the Mx metal line 353 and the via 348. An inner metal plate may be connected to the Mx metal line 354 and the via 350. The structure 300 may differ from the structure 100 and the structure 200 in an outline of a shape of the opening 324 and an outline of a shape of the corner opening 326. The outline of the shape of the opening 324 and the outline of the shape of the corner opening 326 may be a circular shape from above. The structure 300 may have similar benefits as the structure 200 and the structure 100.

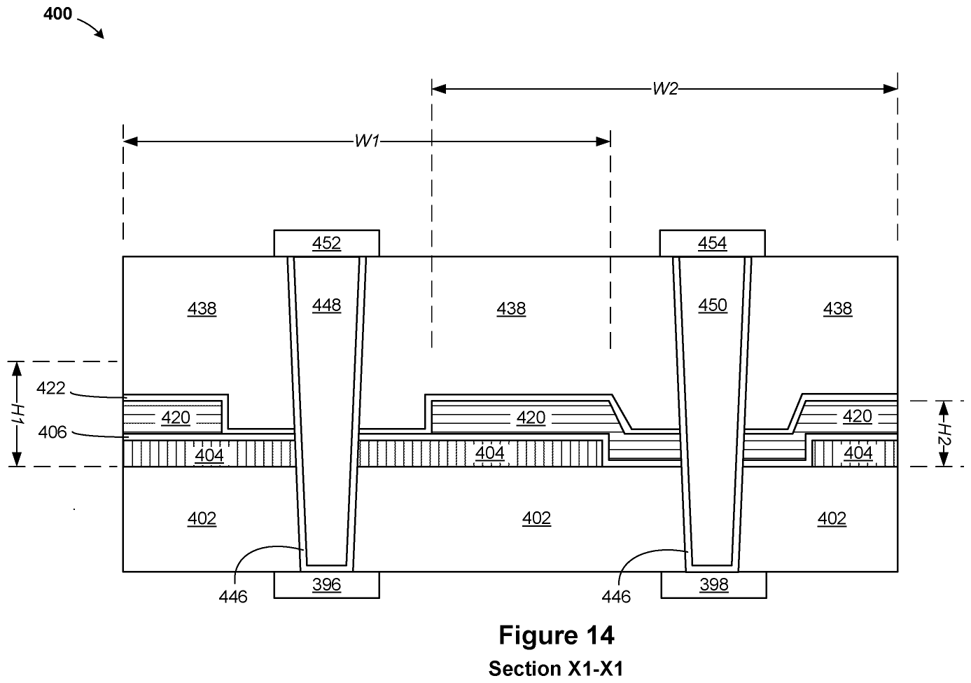

Referring now to FIG. 14, a semiconductor structure 400 (hereinafter “structure”) at an intermediate stage of fabrication is shown according to an exemplary embodiment. FIG. 14 is a cross sectional view of the structure 400 along section line X1-X1. The structure 400 may be formed or provided. The structure 400 may include an Mx-1 metal line 396, an Mx-1 metal line 398, an inter-layer dielectric (hereinafter “ILD”) 402, a first plate 404, an insulator 406, an inner plate 420 and an insulator 422. The structure 400 may include an inter-layer dielectric (hereinafter “ILD”) 438, an Mx metal line 452, an Mx metal line 454, a liner 446, a via 448 and a via 550.

The structure 400 may be formed as described for the structure 100. Components in the structure 400 may be formed as described for components with similar names in the structure 100. An outer metal plate may be the first plate 404, which is connected to the Mx-1 metal line 396, the Mx metal line 452 and the via 448. The inner plate 420 may be connected to the Mx-1 metal line 398, the Mx metal line 454 and the via 450. The structure 400 may differ from the structure 300 and the structure 200 and the structure 100 in that the structure 400 is a two plate MIM capacitor rather than a three plate MIM capacitor. The structure 400 may have similar benefits as the structures 300, 200, 100, and may have openings and corner openings in each of the first plate 404 and the inner plate 420.

In this invention, corners of the first contact window (or contact pad) and the second contact window (or contact pad) do not have the inner plate nor the outer plate, which reduces stress on the MIM capacitor and on a structure using the MIM capacitor. By removing the inner plate and the outer plate from each corner of the contact window, a reliability of the structure using the MIM capacitor is improved.

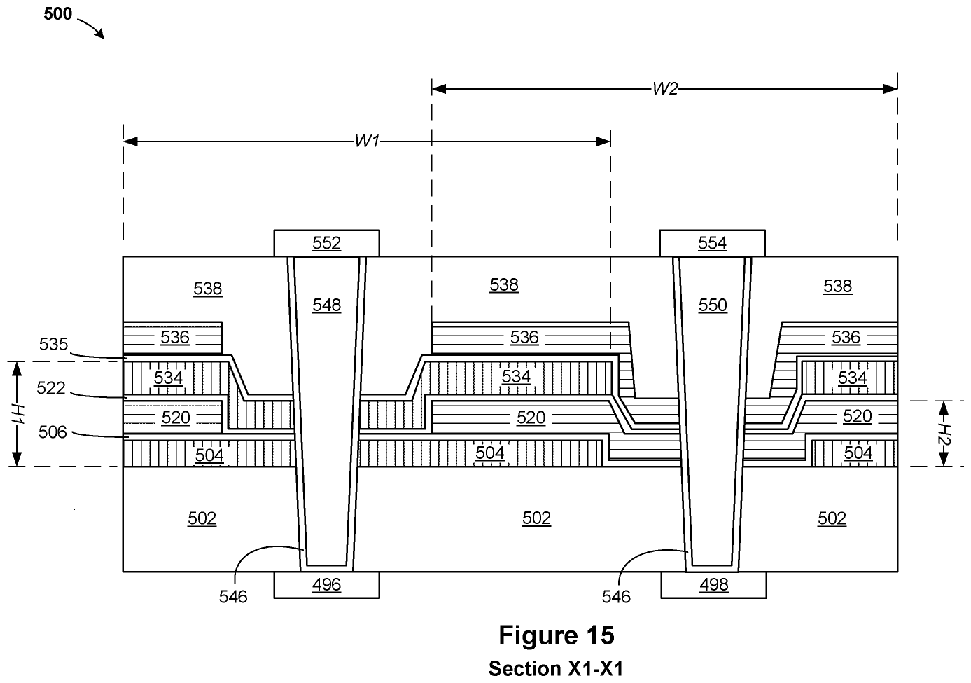

Referring now to FIG. 15, a semiconductor structure 500 (hereinafter “structure”) at an intermediate stage of fabrication is shown according to an exemplary embodiment. FIG. 15 is a cross sectional view of the structure 500 along section line X1-X1. The structure 500 may be formed or provided. The structure 500 may include an Mx-1 metal line 496, an Mx-1 metal line 498, an inter-layer dielectric (hereinafter “ILD”) 502, a first plate 504, an insulator 506, an inner plate 520 and an insulator 522. The structure 500 may include an insulator 535, a second inner plate 536, an inter-layer dielectric (hereinafter “ILD”) 538, a liner 546, an Mx metal line 552, an Mx metal line 554, a via 548 and a via 550.

The structure 500 may be formed as described for the structure 100. Components in the structure 500 may be formed as described for components with similar names in the structure 100. An outer metal plate may be the first plate 504, which is connected to the Mx-1 metal line 496, the Mx metal line 552 and the via 548. The inner plate 520 and the second inner plate 536 may be connected to the Mx-1 metal line 498, the Mx metal line 554 and the via 550. The structure 500 may differ from the structures 400, 300, 200, 100 in that the structure 500 is a four plate MIM capacitor rather than a three plate MIM capacitor. The structure 500 may have similar benefits as the structures 400, 300, 200, 100, and may have openings and corner openings in each of the first plate 404, the second plate 534, the inner plate 420 and the second inner plate 536.

In this invention, corners of the first contact window (or contact pad) and the second contact window (or contact pad) do not have the inner plate nor the outer plate, which reduces stress on the MIM capacitor and on a structure using the MIM capacitor. By removing the inner plate and the outer plate from each corner of the contact window, a reliability of the structure using the MIM capacitor is improved.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
a metal insulator metal capacitor (MIM capacitor) within back end of line circuitry of the semiconductor device; and
an outer plate contact opening of an outer plate of the MIM capacitor, wherein a portion of an inner plate is removed, wherein
portions of the outer plate are removed from corners of the outer plate opening.

2. The semiconductor device according to claim 1, further comprising:
an inner plate contact opening of an inner plate of the MIM capacitor, wherein a portion of the outer plate is removed, wherein
portions of the inner plate are removed from corners of the inner plate opening.

3. The semiconductor device according to claim 1, further comprising:
a second outer plate contact opening of a second outer plate of the MIM capacitor vertically aligned above the outer plate contact opening, wherein
portions of the second outer plate are removed from corners of the second outer plate opening.

4. The semiconductor device according to claim 2, further comprising:
a second inner plate contact opening of a second inner plate of the MIM capacitor vertically aligned above the inner plate contact opening, wherein a portion of the second outer plate is removed, wherein
portions of the second inner plate are removed from corners of the second inner plate opening.

5. The semiconductor device according to claim 1, further comprising:
a first via connected to and through the outer plate contact opening is connected to a first Mx-1 metal line and is connected to a first Mx metal line.

6. The semiconductor device according to claim 2, further comprising:
a second via connected to and through the inner plate contact opening is connected to a second Mx-1 metal line and is connected to a second Mx metal line.

7. A semiconductor device comprising:
a metal insulator metal capacitor (MIM capacitor) within back end of line circuitry of the semiconductor device; and
a non-rectangular contact opening of an outer plate of the MIM capacitor.

8. The semiconductor device according to claim 7, further comprising:
a non-rectangular contact opening of an inner plate of the MIM capacitor.

9. The semiconductor device according to claim 7, wherein
the non-rectangular contact opening of the outer plate of the MIM capacitor is circular shaped from a top view.

10. The semiconductor device according to claim 7, wherein
the non-rectangular contact opening of the outer plate of the MIM capacitor is octagon shaped from a top view.

11. The semiconductor device according to claim 7, wherein
the non-rectangular contact of a contact opening of the MIM capacitor is cross shaped from a top view.

12. The semiconductor device according to claim 11, further comprising:
a first via connected to and through the non-rectangular contact opening of the outer plate of the MIM capacitor is connected to a first Mx-1 metal line and is connected to a first Mx metal line.

13. A method of forming a semiconductor device comprising:
forming a metal insulator metal capacitor (MIM capacitor) within back end of line circuitry of the semiconductor device; and
an outer plate contact opening of an outer plate of the MIM capacitor, wherein a portion of an inner plate is removed, wherein
portions of the outer plate are removed from corners of the outer plate opening.

14. The semiconductor device according to claim 13, further comprising:
forming an inner plate contact opening of an inner plate of the MIM capacitor, wherein a portion of the outer plate is removed, wherein
portions of the inner plate are removed from corners of the inner plate opening.

15. The method according to claim 13, further comprising:
forming a second outer plate contact opening of a second outer plate of the MIM capacitor vertically aligned above the outer plate contact opening, wherein
portions of the second outer plate are removed from corners of the second outer plate opening.

16. The method according to claim 14, wherein
forming a second inner plate contact opening of a second inner plate of the MIM capacitor vertically aligned above the inner plate contact opening, wherein a portion of the second outer plate is removed, wherein
portions of the second inner plate are removed from corners of the second inner plate opening.

17. The method according to claim 13, further comprising:
forming a first via connected to and through the outer plate contact opening is connected to a first Mx-1 metal line and is connected to a first Mx metal line.

18. The method according to claim 14, further comprising:
forming a second via connected to and through the inner plate contact opening is connected to a second Mx-1 metal line and is connected to a second Mx metal line.

19. The method according to claim 13, further comprising:
forming a non-rectangular contact opening of the outer plate of the MIM capacitor.

20. The method according to claim 14, further comprising:
forming a non-rectangular contact opening of the inner plate of the MIM capacitor.
